(19) United States
(12) Patent Application Publication
(10) Pub. No.: US 2025/0096068 A1
(43) Pub. Date: Mar. 20, 2025

(54) SEMICONDUCTOR DEVICE

(71) Applicant: FUJI ELECTRIC CO., LTD., Kawasaki-shi (JP)

(72) Inventors: Naoki TAKIZAWA, Matsumoto-City (JP); Kouki NAKAKURA, Matsumoto-City (JP)

(73) Assignee: FUJI ELECTRIC CO., LTD., Kawasaki-shi (JP)

(21) Appl. No.: 18/783,104

(22) Filed: Jul. 24, 2024

(30) Foreign Application Priority Data
Sep. 14, 2023 (JP) 2023-149068

(51) Int. Cl. H01L 23/373; H01L 21/48; H01L 23/047; H01L 25/07; H01L 25/18

(52) U.S. Cl. CPC H01L 23/3735; H01L 21/4807; H01L 21/4817; H01L 23/047; H01L 25/072; H01L 25/18

(57) ABSTRACT

A semiconductor device, including: a first board and a second board facing each other with a space therebetween; a heat dissipation base having a front surface, on which the first board is bonded via a first f solder layer and the second board is bonded via a second solder layer; and a resist formed along the first solder layer and the second solder layer. The first solder layer has an edge portion thereof, which is a first edge portion, facing the second solder layer. The second solder layer has an edge portion thereof, which is a second edge portion, facing the first solder layer. The resist is in contact with the first edge portion and the second edge portion.

### CROSS-REFERENCE TO RELATED APPLICATION

This application is based upon and claims the benefit of priority of the prior Japanese Patent Application No. 2023-149068, filed on Sep. 14, 2023, the entire contents of which are incorporated herein by reference.

### BACKGROUND OF THE INVENTION

### 1. Field of the Invention

The embodiments discussed herein relate to a semiconductor device.

### 2. Background of the Related Art

A semiconductor device includes a base board, an insulated circuit board formed on the base board via solder, and a semiconductor chip formed on the insulated circuit board via solder (see, for example, Japanese Laid-open Patent Publication No. 2016-164919). In this semiconductor device, a resist is formed around the solder on the base board (see, for example, Japanese Laid-open Patent Publication No. 2010-212723 and Japanese Laid-open Patent Publication No. 2013-201289). In addition, a resist is formed around the solder on the insulated circuit board (see, for example, Japanese Laid-open Patent Publication No. 2013-236037 and Japanese Laid-open Patent Publication No. 2017-117813).

### SUMMARY OF THE INVENTION

According to one mode of the embodiments, there is provided a semiconductor device, including: a first board and a second board facing each other with a space therebetween; a heat dissipation base having a front surface, on which the first board is bonded via a first solder layer and the second board is bonded via a second solder layer; and a resist formed along the first solder layer and the second solder layer, wherein the first solder layer has an edge portion thereof facing the second solder layer, the edge portion being a first edge portion, the second solder layer has an edge portion thereof facing the first solder layer, the edge portion being a second edge portion, and the resist is in contact with the first edge portion and the second edge portion.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device according to a first embodiment;

FIG. 2 is a sectional view of the semiconductor device according to the first embodiment;

FIG. 3 is a sectional view of a main part of the semiconductor device according to the first embodiment;

FIG. 4 is the first half of a flowchart of a semiconductor device manufacturing method according to the first embodiment;

FIG. 5 is the second half of the flowchart of the semiconductor device manufacturing method according to the first embodiment;

FIG. 6 is a plan view of a heat dissipation base prepared in a preparation process included in the semiconductor device manufacturing method according to the first embodiment;

FIG. 7 is a plan view of the heat dissipation base on which a resist prepared in the preparation process included in the semiconductor device manufacturing method according to the first embodiment;

FIG. 8 is a plan view illustrating a semiconductor unit bonding process (setting of a positioning jig) included in the semiconductor device manufacturing method according to the first embodiment;

FIG. 9 is a sectional view illustrating the semiconductor unit bonding process (setting of the positioning jig) included in the semiconductor device manufacturing method according to the first embodiment;

FIG. 10 is a sectional view illustrating the semiconductor unit bonding process (setting of semiconductor units) included in the semiconductor device manufacturing method according to the first embodiment;

FIG. 11 is a sectional view illustrating the semiconductor unit bonding process (cooling) included in the semiconductor device manufacturing method according to the first embodiment;

FIG. 12 is a sectional view illustrating a semiconductor unit bonding process (heating) included in a semiconductor device manufacturing method according to a reference example;

FIG. 13 is a sectional view illustrating the semiconductor unit bonding process (cooling) included in the semiconductor device manufacturing method according to the reference example;

FIG. 14 is a sectional view of a main part, illustrating the semiconductor unit bonding process (removal of a positioning jig) included in the semiconductor device manufacturing method according to the reference example;

FIG. 15 is a graph illustrating displacement of an insulated circuit board with respect to the width of the resist;

FIG. 16 is a plan view of a semiconductor device according to a second embodiment; and

FIG. 17 is a sectional view of a main part of the semiconductor device according to the second embodiment.

### DETAILED DESCRIPTION OF THE INVENTION

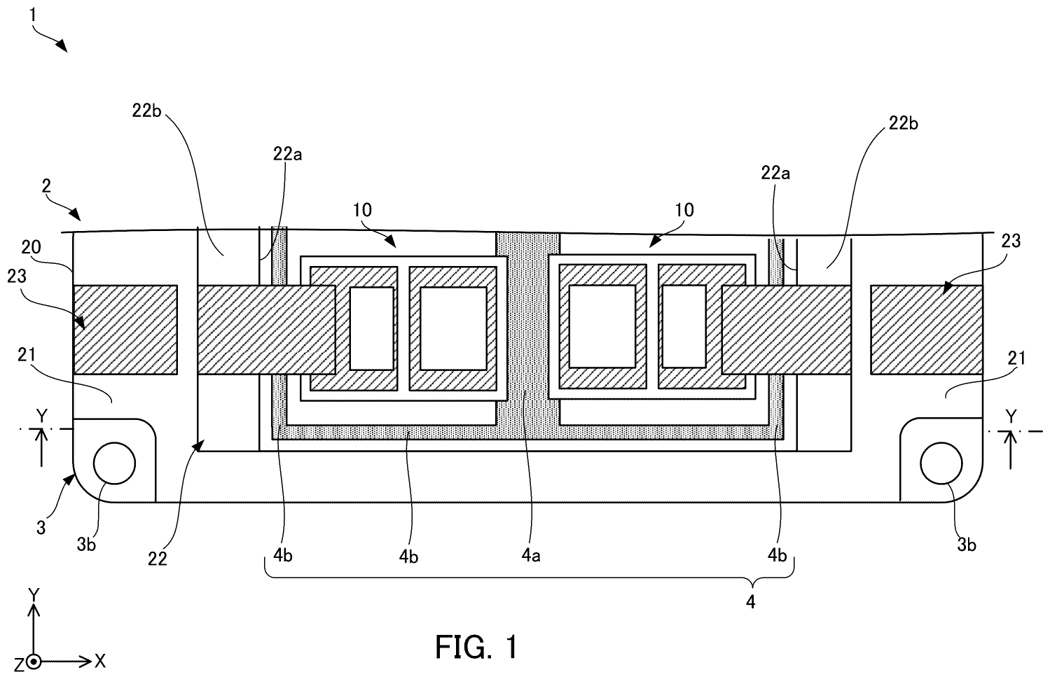

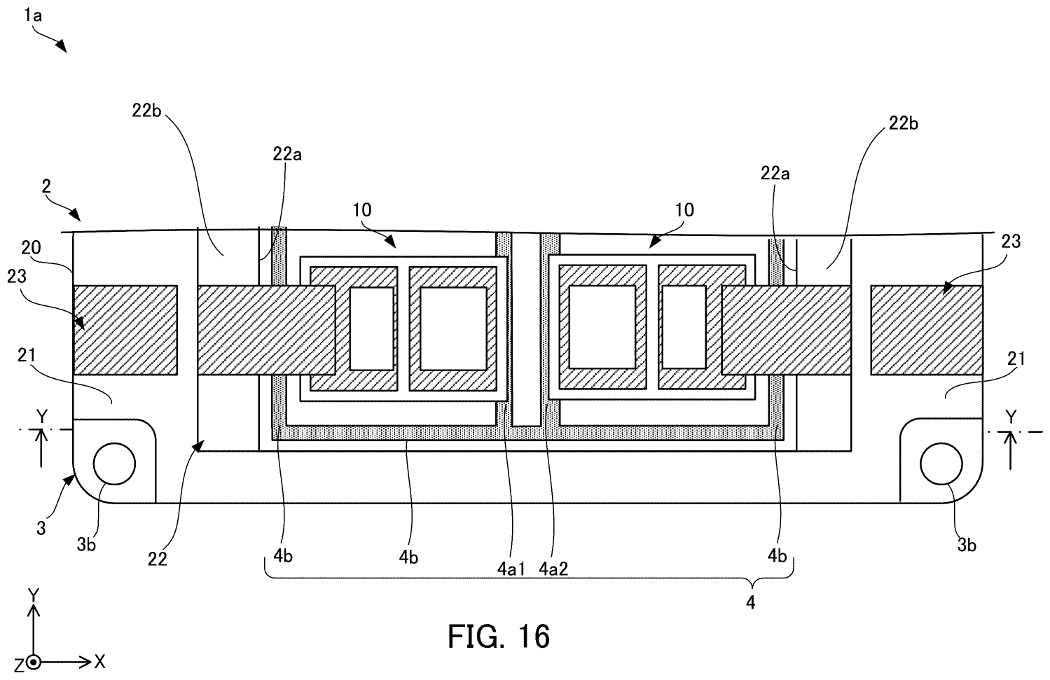

Hereinafter, embodiments will be described with reference to the accompanying drawings. In the following description, regarding semiconductor devices 1 and 1a in FIGS. 1 and 16, terms “front surface” and “top surface” each express an X-Y surface facing upward (the +Z direction). Likewise, regarding the semiconductor devices 1 and 1a in FIGS. 1 and 16, a term “up” expresses the upper direction (the +Z direction). Regarding the semiconductor devices 1 and 1a in FIGS. 1 and 16, terms “rear surface” and “bottom surface” each express an X-Y surface facing downward (the −Z direction). Likewise, regarding the semiconductor devices 1 and 1a in FIGS. 1 and 16, a term “down” expresses the lower direction (the −Z direction). In all the other drawings, the above terms also mean their respective directions as appropriate. Regarding the semiconductor devices 1 and 1a in FIGS. 1 and 16, terms “higher level” and “upper level” express an upper location (in the +Z direction). Likewise, regarding the semiconductor devices 1 and 1a in FIGS. 1 and 16, a term “lower level” expresses a lower location (in the −Z direction). The terms “front surface”, “top surface”, “up”, “rear surface”, “bottom surface”, “down”, and “side surface” are simply used as convenient expressions to determine relative positional relationships and do not limit the technical ideas of the embodiments. For example, the terms “up” and “down” may mean directions other than the vertical directions with respect to the ground. That is, the directions expressed by “up” and “down” are not limited to the directions relating to the gravitational force. In addition, in the following description, when a component contained in a material represents 80 vol % or more of the material, this component will be referred to as “main component” of the material (If the material contains a filler, the percentage is calculated without the filler). In addition, an expression “approximately the same” may be used when an error between two elements is within in ±10%. In addition, even when two elements are not exactly perpendicular, orthogonal, or parallel to each other, the two elements may be described as being “perpendicular”, “orthogonal”, or “parallel” to each other if the error is within ±10°.

### First Embodiment

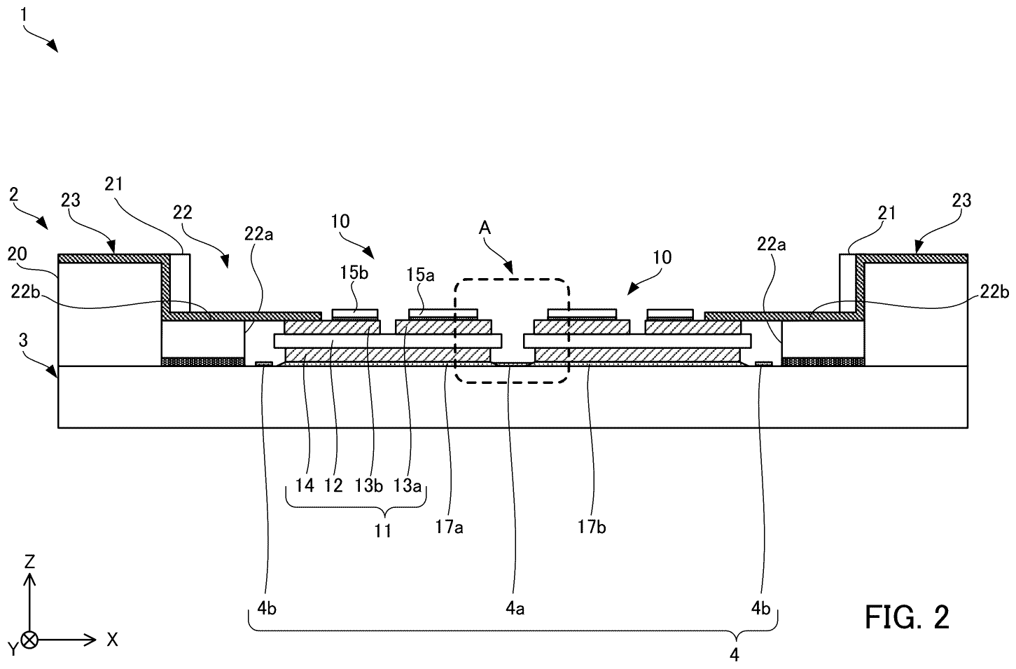

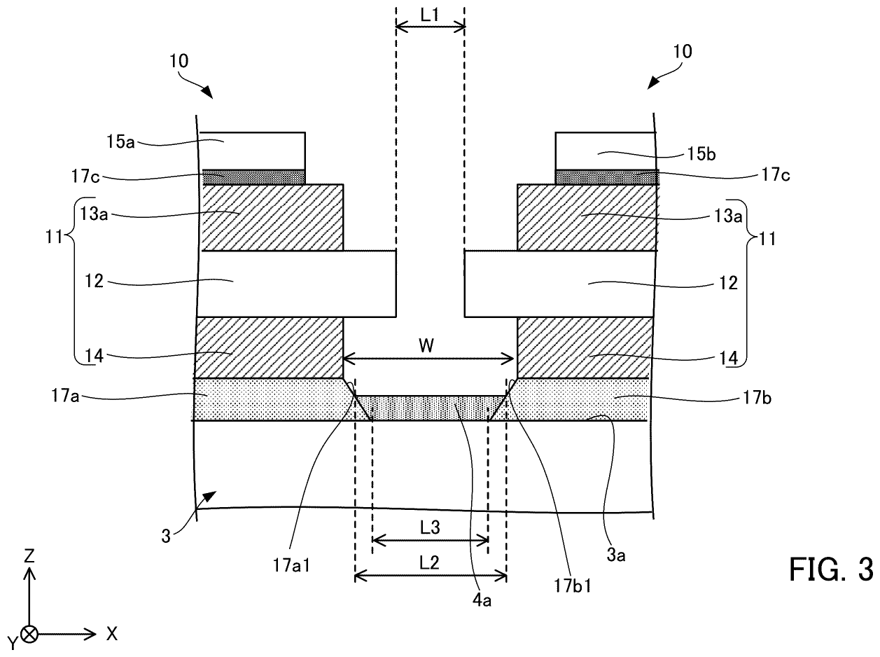

A semiconductor device according to a first embodiment will be described with reference to FIGS. 1 to 3. FIG. 1 is a plan view of a semiconductor device according to a first embodiment, and FIG. 2 is a sectional view of the semiconductor device according to the first embodiment. FIG. 3 is a sectional view of a main part of the semiconductor device according to the first embodiment. Specifically, FIG. 1 is a plan view of the −Y direction half of a semiconductor device 1. FIG. 2 is a sectional view taken along a dash-dotted line Y-Y in FIG. 1. FIG. 3 is an enlarged view of an area A enclosed by a broken line in FIG. 2. Illustration of sealing material is omitted in FIGS. 1 to 3.

As illustrated in FIGS. 1 and 2, this semiconductor device 1 includes semiconductor units 10, a case 2, and a heat dissipation base 3. The case 2 has a storage area 22, which may be sealed with sealing material. This sealing material may be, for example, a thermosetting resin to which a filler has been added. Examples of the thermosetting resin include epoxy resin, phenol resin, maleimide resin, and polyester resin. The filler may be an insulating ceramic material having a high thermal conductivity, for example. Examples of the filler include silicon oxide, aluminum oxide, boron nitride, and aluminum nitride.

Four semiconductor units 10 are disposed on a front surface 3a of the heat dissipation base 3. These four semiconductor units 10 are separated from one another in two rows and two columns in a center portion of the front surface 3a of the heat dissipation base 3.

As illustrated in FIG. 3, assuming that the distance between the insulating plates 12 of the insulated circuit boards 11 of two semiconductor units 10 is denoted by L1, and assuming that the distance between metal plates 14 of these insulated circuit boards 11 is denoted by W, the distance between the furthest points of solder layers 17a and 17b is also denoted by W. In addition, the maximum width (in the ±X directions) of an inner resist portion 4a, which will be described below, is denoted by L2. In practice, because the inner resist portion 4a is sufficiently thinner than the solder layers 17a and 17b, the length of the inner resist portion 4a in the width direction (in the ±X directions) may be practically considered to be the width L2. In FIGS. 2 and 3, two semiconductor units 10 disposed adjacent to each other are seen in the +Y direction. Although not illustrated, even when two semiconductor units 10 disposed adjacent to each other are seen in the −Y direction, these two semiconductor units 10 are also bonded to the heat dissipation base 3 via solder layers. Even when two semiconductor units 10 disposed adjacent to each other are seen in the +X direction, the distance L1, the distance W, and the width L2 are also applied as described above.

The width L2 is greater than the distance L1. The width L2 is between 1.5 mm and 2.5 mm, inclusive. For example, the width L2 is 2.0 mm. The distance W between the metal plates 14 of the insulated circuit boards 11 is, for example, between 4.4 mm and 4.8 mm, inclusive.

Because the solder layers 17a and 17b each have a fillet portion, a distance L3 between ends of the fillet portions of the solder layers 17a and 17b is less than the distance W. In FIG. 3, the ends of the fillet portions of the solder layers 17a and 17b may be located on the inner side of ends of the insulating plates 12 located above the solder layers 17a and 17b. In addition, the ends of the fillet portions of the solder layers 17a and 17b may be located outer side of ends of the metal plates 14 directly above the solder layers 17a and 17b. Thus, the width L2 may be considered to correspond to the distance L3 between the ends of the fillet portions of the solder layers 17a and 17b. Thus, the distance between the ends of the fillet portions of the solder layers 17a and 17b is also between 1.5 mm and 2.5 mm, inclusive. The solder layers 17a and 17b each have a thickness between 0.23 mm and 0.27 mm, inclusive, for example. The number of semiconductor units 10 is an example. Any number of semiconductor units 10 may be formed based on the function of the semiconductor device 1.

The individual semiconductor unit 10 includes an insulated circuit board 11 (first or second board) and semiconductor chips 15a and 15b, each of which is disposed on the front surface of the insulated circuit board 11 via a solder layer 17c (see FIG. 3). The rear surface of the semiconductor unit 10 is bonded to the front surface 3a of the heat dissipation base 3 via the solder layer 17a or 17b (first or second solder layer).

Lead-free solder is used as the solder layers 17a, 17b, and 17c. The lead-free solder contains a tin-silver-copper alloy, a tin-zinc-bismuth alloy, a tin-copper alloy, or a tin-silver-indium-bismuth alloy as its main component, for example. The solder layers 17a, 17b, and 17c may also contain an additive such as nickel, germanium, cobalt, or a silicon. Since the solder layers 17a, 17b, and 17c containing such additive have improved wettability, luster, and bonding strength, the reliability is improved.

The individual insulated circuit board 11 has a rectangular shape in plan view. The insulated circuit board 11 includes an insulating plate 12 (first or second insulating plate), conductive plates 13a and 13b formed on the front surface of the insulating plate 12, and a metal plate 14 (first or second metal plate) formed on the rear surface of the insulating plate 12. In plan view, the outline of each of the conductive plates 13a and 13b and the outline of the metal plate 14 are smaller than that of the insulating plate 12, and the conductive plates 13a and 13b and the metal plate 14 are formed on the inner side of the insulating plate 12. The shape and the number of conductive plates 13a and 13b are only examples.

The semiconductor chips 15a and 15b are bonded to the front surface of the conductive plates 13a and 13b, respectively, via the solder layer 17c. The conductive plates 13a and 13b are formed on the entire surface of the insulating plate 12, excepting the edge portions of the insulating plate 12. Preferably, in plan view, end portions of the conductive plates 13a and 13b, the end portions facing the outer periphery of the insulating plate 12, overlap the outer periphery end portions of the metal plate 14. Thus, regarding the insulated circuit board 11, the stress balance between the conductive plates 13a and 13b formed on the front surface of the insulating plate 12 and the metal plate 14 formed on the rear surface of the insulating plate 12 is maintained. Occurrence of excessive warpage and damage such as a crack in the insulating plate 12 is prevented. The conductive plates 13a and 13b are each made of a material having an excellent electrical conductivity. Examples of the material include copper, aluminum, and an alloy containing at least one of these kinds of elements. The conductive plates 13a and 13b may each be plated with a material having an excellent corrosion resistance. The material used for this plating is, for example, nickel, a nickel-phosphorus alloy, or a nickel-boron alloy. The plating film thickness is 10 μm or less. The conductive plates 13a and 13b on the insulating plate 12 may be formed by forming a metal plate on the front surface of the insulating plate 12 and by etching this metal plate, for example. Alternatively, the conductive plates 13a and 13b may be first cut out from a metal plate and next bonded to the front surface of the insulating plate 12. The conductive plates 13a and 13b included in the semiconductor device 1 according to the present embodiment are only examples. For example, the number, shape and size of these conductive plates may be suitably set as needed. The front surface of each of the conductive plates 13a and 13b may also be considered as the front surface of the insulated circuit board 11.

The rear surface of the individual metal plate 14 is bonded to the front surface 3a of the heat dissipation base 3 via the solder layer 17a or 17b. The metal plate 14 is made of a metal material having an excellent thermal conductivity. Examples of the metal material include copper, aluminum, and an alloy containing at least one of these kinds of elements. The thickness of the metal plate 14 may be, for example, between 0.25 mm and 0.35 mm, inclusive. The surface of the metal plate 14 may be plated to improve its corrosion resistance. The material used for this plating contains nickel. For example, the material is nickel, a nickel-phosphorus alloy, or a nickel-boron alloy. The rear surface of the metal plate 14 may also be considered as the rear surface of the insulated circuit board 11.

For example, the individual insulated circuit board 11 having the above-described construction is a direct copper bonding (DCB) board or an active metal brazed (AMB) board. A resin insulating board may alternatively be used as the insulated circuit board 11. With this insulated circuit board 11, the heat generated by the semiconductor chips 15a and 15b, which will be described below, is transferred to the rear surface of the insulated circuit board 11 via the conductive plates 13a and 13b, the insulating plate 12, and the metal plate 14, and is consequently dissipated.

The main component of the semiconductor chips 15a and 15b is, for example, silicon, silicon carbide, or gallium nitride. The semiconductor chip 15a includes a switching element, which is, for example, an insulated gate bipolar transistor (IGBT) or a power metal-oxide-semiconductor field-effect transistor (MOSFET). If the semiconductor chip 15a includes an IGBT, the semiconductor chip 15a includes a collector electrode as a main electrode (input electrode) on its rear surface, and includes a gate electrode as a control electrode and an emitter electrode as a main electrode (output electrode) on its front surface. If the semiconductor chip 15a includes a power MOSFET, the semiconductor chip 15a includes a drain electrode as a main electrode (input electrode) on its rear surface, and includes a gate electrode as a control electrode and a source electrode as a main electrode (output electrode) on its front surface.

In addition, the semiconductor chip 15b includes a diode electrode. The diode element uses a Schottky barrier diode (SBD) or a P-intrinsic-N (PiN) diode as a freewheeling diode (FWD), for example. This semiconductor chip 15b includes a cathode electrode as a main electrode (output electrode) on its rear surface, and includes an anode electrode as a main electrode (input electrode) on its front surface.

In place of the semiconductor chips 15a and 15b, a semiconductor chip including a switching element may be used. The main component of this semiconductor chip may be silicon, for example. For example, the switching element may be a reverse-conducting (RC)-IGBT. The RC-IGBT is a semiconductor element obtained by forming an IGBT and an FWD in anti-parallel on one chip. The semiconductor chip in this case may include a collector electrode as a main electrode (input electrode) on its rear surface, and may include a gate electrode as a control electrode and an emitter electrode as a main electrode (output electrode) on its front surface.

As another switching element used in place of the semiconductor chips 15a and 15b, a power MOSFET whose main component is silicon carbide may be used. A power MOSFET whose body diode functions as an FWD may be used. For example, this semiconductor chip includes a drain electrode as a main electrode (input electrode) on its rear surface, and includes a gate electrode as a control electrode and a source electrode as a main electrode (output electrode) on its front surface.

The case 2 includes a frame portion 20 and external connection terminals 23 embedded in the frame portion 20. In plan view, the frame portion 20 has a rectangular frame shape enclosing the storage area 22. The storage area 22 is an open area in the center of a front surface 21 of the case 2.

A step 22b is formed on each of the short sides of the storage area 22 of the frame portion 20. Specifically, these steps 22b face each other and protrude from the inner walls of the short side portions of the frame portion 20, the inner walls facing each other. Inner walls 22a connected to their respective steps 22b face the storage area 22.

The frame portion 20 is formed by injection molding that uses thermoplastic resin containing a filler. The resin is, for example, polyphenylene sulfide resin, polybutylene terephthalate resin, or polyamide resin. The main component of the filler may be, for example, glass fiber, glass bead, calcium carbide, talc, magnesium oxide, or aluminum hydroxide.

The individual external connection terminal 23 has a flat plate shape and has an L shape in side view. The external connection terminals 23 are integrally formed with the frame portion 20. The individual external connection terminal 23 has an inner end portion and an outer end portion. The inner end portion is disposed on a corresponding one of the steps 22b, extends toward the center of the storage area 22, and is electrically and mechanically connected to the insulated circuit board 11 of a corresponding one of the semiconductor units 10. The outer end portion is formed on the front surface 21 of the frame portion 20.

These external connection terminals 23 are each made of a material having an excellent electrical conductivity. For example, the material is copper, aluminum, or an alloy containing at least one of these kinds of elements. Overall, the individual external connection terminal 23 has the same thickness. The external connection terminal 23 may be plated with a material having an excellent corrosion resistance. For example, the material is aluminum, nickel, titanium, chromium, molybdenum, tantalum, niobium, tungsten, vanadium, bismuth, zirconium, hafnium, gold, silver, platinum, palladium, or an alloy containing at least one these kinds of elements.

The rear surface of the frame portion 20 of the case 2 is bonded to the outer periphery of the front surface 3a of the heat dissipation base, to which the semiconductor units 10 have been bonded, via adhesive (illustration of a reference character is omitted). As a result, the semiconductor units 10 are stored in the storage area 22 of the frame portion 20. The storage area 22 of the frame portion 20 may be covered with a lid (not illustrated), and the storage area 22 and the lid may be bonded to each other by using adhesive. For example, the adhesive is thermosetting resin-based adhesive or elastomer-based adhesive. The main component of the thermosetting resin-based adhesive is, for example, epoxy resin or phenol resin. The main component of the elastomer-based adhesive is, for example, silicone rubber or chloroprene rubber.

Although not illustrated in FIGS. 1 and 2, the frame portion 20 may integrally include control terminals to which control signals are input from the outside, as is the case with the external connection terminals 23. The control terminals may also have inner end portions and outer end portions. An individual inner end portion may be electrically connected to a control terminal of a semiconductor chip 15a via a wire. An individual outer end portion may appear on the front surface 21 of the frame portion 20. The wire is made of a material having an excellent electrical conductivity. The material is, for example, gold, silver, copper, aluminum, or an alloy containing at least one these kinds of elements.

FIGS. 1 and 2 illustrate, as an example, a case in which the external connection terminals 23 are electrically and mechanically connected to their respective insulated circuit boards 11. The inner end portion of each connection terminal 23 may be disposed on a external corresponding one of the steps 22b, and the inner end portion and a corresponding one of the insulated circuit boards 11 may be connected to each other via a wiring member. The wring member is made of a material having an excellent electrical conductivity. The material is, for example, gold, silver, copper, aluminum, or an alloy containing at least one these kinds of elements. The wiring member is, for example, a wire or a lead frame.

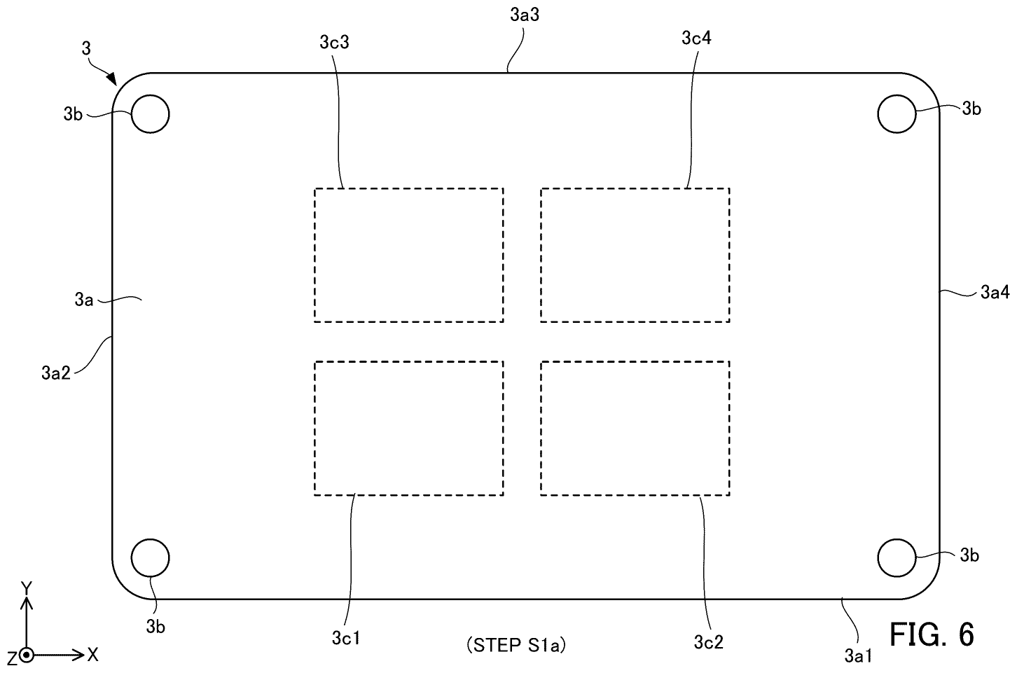

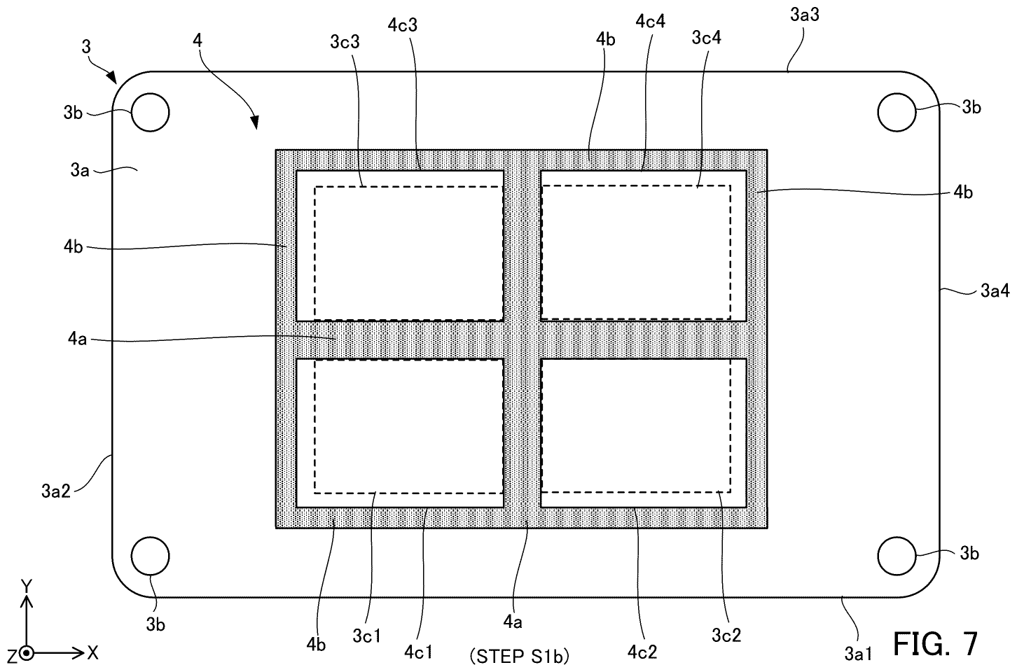

The heat dissipation base 3 has a rectangular shape in plan view. The planar shape and area of the heat dissipation base 3 may match the planar shape and area of the case 2. In plan view, each of the four corner portions of the heat dissipation base 3 may form a right angle or may be rounded or chamfered. The heat dissipation base 3 has the front surface 3a. In addition, the heat dissipation base 3 has a long side surface 3a1, a short side surface 3a2, a long side surface 3a3, and a short side surface 3a4 enclosing the front surface 3a in four directions in plan view (see FIGS. 6 and 7). In addition, the heat dissipation base 3 has fixing holes 3b in its four corner portions in plan view. These fixing holes 3b penetrate the heat dissipation base 3. The semiconductor device 1 is disposed and fixed on a predetermined area by inserting bolts into the fixing holes 3b.

The heat dissipation base 3 is made of a metal material having an excellent thermal conductivity. The material is, for example, copper, aluminum, or an alloy containing at least one these kinds of elements. In the present embodiment, the material contains copper. Although the thickness of the heat dissipation base 3 depends on the size of the semiconductor device 1, the thickness may be, for example, between 2.5 mm and 3.5 mm, inclusive.

A cooling unit (not illustrated) may be attached to the rear surface of the heat dissipation base 3 via a thermally conductive member. The thermally conductive member is a thermal interface material (TIM). The TIM is, for example, a generic term for various kinds of materials such as thermally conductive grease, elastomer sheet, room temperature vulcanization (RTV) rubber, gel, phase-change material, solder, and silver solder. In this way, the heat dissipation of the semiconductor device 1 is improved. The cooling unit in this case is made of a metal material having an excellent thermal conductivity, for example. The metal material is, for example, aluminum, iron, silver, copper, or an alloy containing at least one these kinds of elements. The cooling unit is, for example, a heatsink including at least one fin or a water-cooled cooling device.

A resist 4 is formed on the front surface 3a of the heat dissipation base 3. The resist 4 contains carbon or metal oxide as its main component, for example. The metal oxide is, for example, nickel oxide. If carbon is used as its main component, the resist 4 is formed by drawing a line with a pencil on an area where the resist 4 is to be formed on the front surface 3a. If nickel oxide is used as its main component, a laser beam is emitted to an area where the resist 4 is to be formed on the front surface 3a of the heat dissipation base 3, the front surface 3a having been plated in advance with a plating film containing nickel. As a result, the resist 4 containing a nickel oxide film as its main component is formed.

The above-described resist 4 includes the inner resist portion 4a (resist) and an outer resist portion 4b. Overall, the resist 4 has approximately the same thickness. The inner resist portion 4a is formed in the space among the four insulated circuit boards 11 in plan view on the front surface 3a of the heat dissipation base 3 along the solder layers bonding the insulated circuit boards 11 to the front surface 3a. FIG. 3 illustrates a case in which the inner resist portion 4a is formed between the solder layers 17a and 17b bonding their respective insulated circuit boards 11 to the front surface 3a. Specifically, the inner resist portion 4a is in contact with an edge portion 17a1 (first edge portion) of the solder layer 17a, the edge portion 17a1 facing the solder layer 17b, and is in contact with an edge portion 17b1 (second edge portion) of the solder layer 17b, the edge portion 17b1 facing the solder layer 17a. That is, the inner resist portion 4a is formed on the front surface 3a of the heat dissipation base 3 such that the inner resist portion 4a fills the entire space between the solder layers 17a and 17b. The thickness of the inner resist portion 4a is sufficiently thinner than the thickness of the solder layers 17a and 17b. The inner resist portion 4a has water repellency against solder, and prevents the solder layers bonding the insulated circuit boards 11 to the front surface 3a of the heat dissipation base 3 from spreading to the inner side.

The outer resist portion 4b is formed at the outer periphery enclosing the four insulated circuit boards 11 disposed on the front surface 3a of the heat dissipation base 3. The outer resist portion 4b includes a long side portion, a short side portion, a long side portion, and a short side portion that are parallel to the long side surface 3a1, the short side surface 3a2, the long side surface 3a3, and the short side surface 3a4 of the heat dissipation base 3 in plan view. Any corner portion of the outer resist portion 4b where a long side portion and a short side portion connect to each other may form a right angle or may be rounded or chamfered. Each side portion of the outer resist portion 4b is formed between an inner wall of the frame portion 20 of the case 2 and an insulated circuit board 11 (solder layer). For example, as illustrated in FIG. 2, each side portion of the outer resist portion 4b is formed between the solder layer 17a or 17b bonding an insulated circuit board 11 to the heat dissipation base 3 and an inner wall 22a of the frame portion 20. That is, unlike the inner resist portion 4a, the outer resist portion 4b does not need to fill the entire space between the solder layer 17a or 17b bonding an insulated circuit board 11 to the heat dissipation base 3 and an inner wall 22a of the frame portion 20 in side view. The width of the outer resist portion 4b may be less than the width L2 of the inner resist portion 4a. The outer resist portion 4b also prevents the solder layers bonding the insulated circuit boards 11 to the front surface 3a of the heat dissipation base 3 from spreading to the outer side.

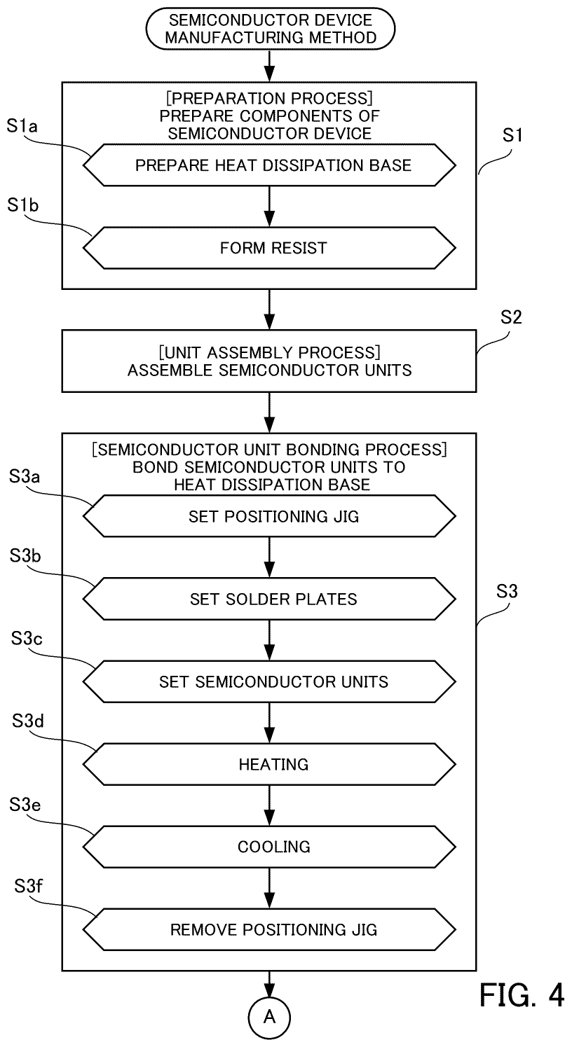

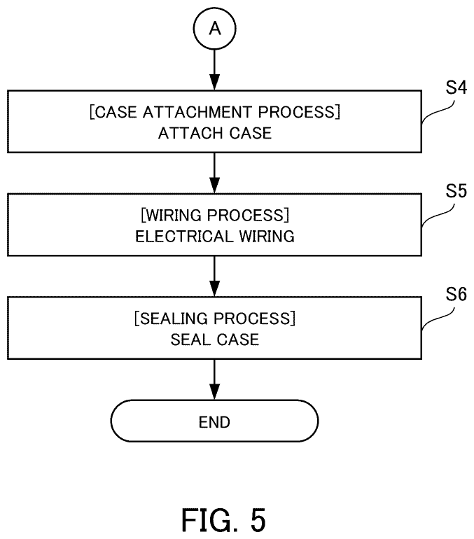

Next, a method for manufacturing the semiconductor device 1 will be described with reference to FIGS. 4 and 5. FIGS. 4 and 5 illustrate a flowchart of a method for manufacturing the semiconductor device according to the first embodiment. After step S3 in FIG. 4, step S4 is FIG. 5 is performed.

First, a preparation process for preparing components of the semiconductor device 1 is performed (step S1 in FIG. 4). Examples of the components prepared in step S1 include the insulated circuit boards 11, the semiconductor chips 15a and 15b, the case 2, and the heat dissipation base 3. In addition to these components, other components needed to manufacture the semiconductor device 1 are also prepared. Manufacturing apparatuses used to manufacture the semiconductor device 1 may also be prepared.

In addition, in the preparation process, the resist 4 is formed on the heat dissipation base 3. The forming of the resist 4 on the heat dissipation base 3 will be described. First, the heat dissipation base 3 is prepared (step S1a in FIG. 4). The heat dissipation base 3 will be described with reference to FIG. 6. FIG. 6 is a plan view of the heat dissipation base prepared in the preparation process included in the semiconductor device manufacturing method according to the first embodiment.

As illustrated in FIG. 6, the heat dissipation base 3 has a rectangular shape in plan view, and may have four rounded corner portions. The heat dissipation base 3 has the front surface 3a. In addition, in plan view, the heat dissipation base 3 has the long side surface 3a1, the short side surface 3a2, the long side surface 3a3, and the short side surface 3a4 enclosing the front surface 3a in the four directions. In addition, in plan view, the fixing holes 3b are formed in the four corner portions of the heat dissipation base 3.

Placement areas 3c1, 3c2, 3c3, and 3c4 are set on the front surface 3a of the heat dissipation base 3. The size of each of these placement areas 3c1, 3c2, 3c3, and 3c4 may match the size of each of the metal plates 14 included in the insulated circuit boards 11 of the semiconductor units 10. The distance between two neighboring placement areas of the placement areas 3c1, 3c2, 3c3, and 3c4 is distance W, which may be, for example, between 1.8 mm and 2.2 mm, inclusive.

Next, the resist 4 is formed on the front surface 3a of the heat dissipation base 3 (step S1b in FIG. 4). The forming of the resist 4 will be described with reference to FIG. 7. FIG. 7 is a plan view of the heat dissipation base on which the resist prepared in the preparation process included in the semiconductor device manufacturing method according to the first embodiment is formed.

First, the outer resist portion 4b is formed on the front surface 3a such that the long side portion, the short side portion, the long side portion, and the short side portion are parallel to the long side surface 3a1, the short side surface 3a2, the long side surface 3a3, and the short side surface 3a4 with a predetermined distance from the placement areas 3c1, 3c2, 3c3, and 3c4. The outer resist portion 4b has a continuous circular frame shape in plan view.

In addition, the inner resist portion 4a is formed such that a part of the inner resist portion 4a is parallel to the long side surface 3a1 and the long side surface 3a3 and such that another part of the inner resist portion 4a is parallel to the short side surface 3a2 and the short side surface 3a4 in the space among the placement areas 3c1, 3c2, 3c3, and 3c4 on the front surface 3a. In FIG. 7, the inner resist portion 4a is formed to fill the space among the placement areas 3c1, 3c2, 3c3, and 3c4. In practice, in view of the spreading of the solder as will be described below, the inner resist portion 4a is formed in the space away from the placement areas 3c1, 3c2, 3c3, and 3c4 by a few millimeters. The inner resist portion 4a has a cross shape in plan view, connects the long side portions of the outer resist portion 4b, and connects the short side portions of the outer resist portion 4b.

Thus, the resist 4 has a rectangular shape in plan view, and has four opening areas 4c1, 4c2, 4c3, and 4c4 inside. Opposing sides of each of the opening areas 4cl, 4c2, 4c3, and 4c4 match opposing side of each of the placement areas 3c1, 3c2, 3c3, and 3c4. The inner resist portion 4a and the outer resist portion 4b may be formed in any order as long as the resist 4 as illustrated in FIG. 7 is drawn.

Next, a unit assembly process for assembling the semiconductor units 10 is performed (step S2 in FIG. 4). The semiconductor chips 15a and 15b are bonded to the conductive plates 13a and 13b of the individual insulated circuit board 11, respectively, via the solder layer 17c, so as to assemble the individual semiconductor unit 10. In the present embodiment, four semiconductor units 10 are assembled.

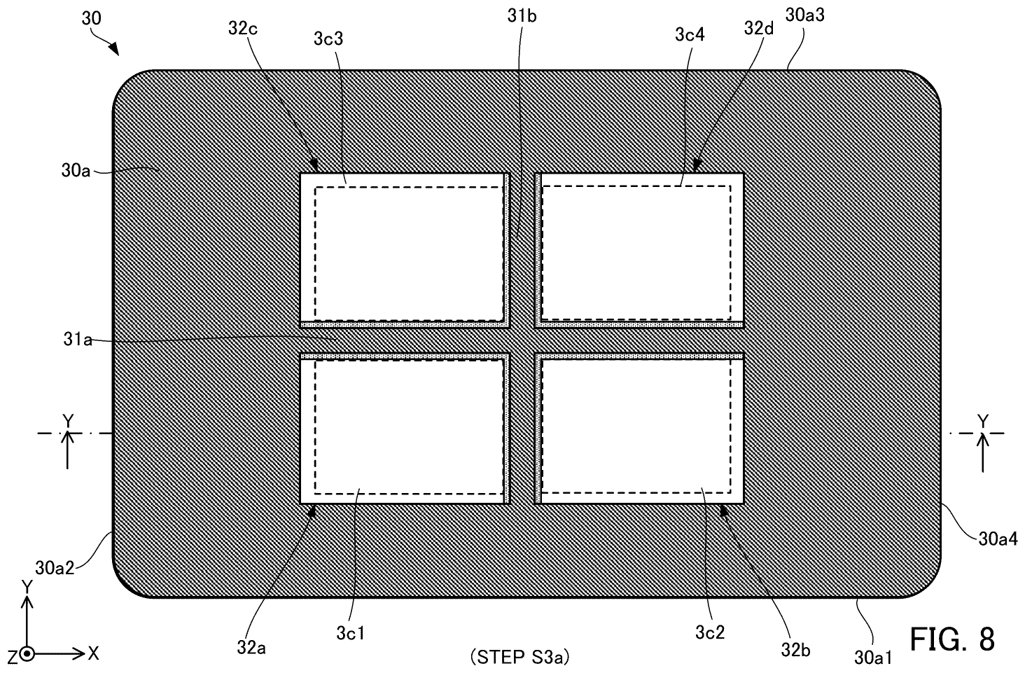

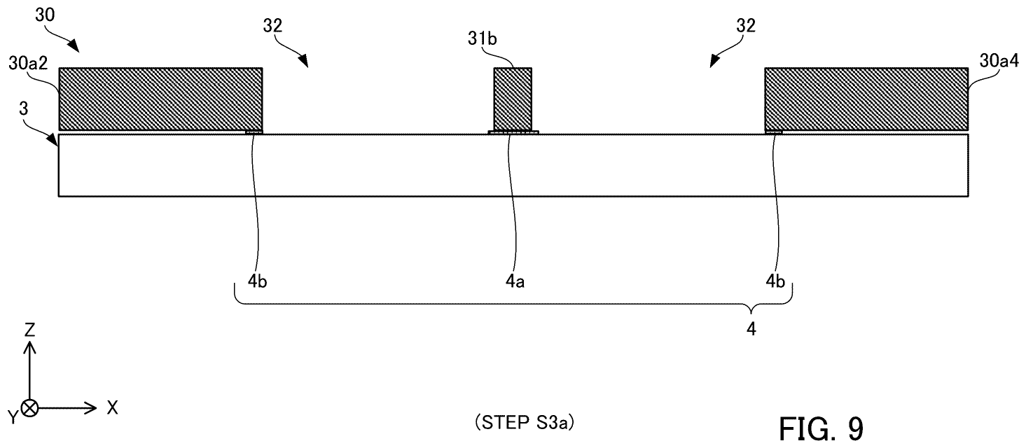

Next, a semiconductor unit bonding process for bonding the semiconductor units 10 to the front surface 3a of the heat dissipation base 3 is performed (step S3 in FIG. 4). To perform the semiconductor unit bonding process, first, a positioning jig 30 is disposed on the front surface 3a of the heat dissipation base 3 (step S3a in FIG. 4). This process will be described with reference to FIGS. 8 and 9. FIG. 8 is a plan view illustrating the semiconductor unit bonding process (setting of a positioning jig) included in the semiconductor device manufacturing method according to the first embodiment. FIG. 9 is a sectional view illustrating the semiconductor unit bonding process (setting of the positioning jig) included in the semiconductor device manufacturing method according to the first embodiment. Specifically, FIG. 9 is a sectional view taken along a dash-dotted line Y-Y in FIG. 8.

As illustrated in FIGS. 8 and 9, the positioning jig 30 is set on the front surface 3a of the heat dissipation base 3. The positioning jig 30 is made of a material having an excellent heat resistance and having a property that prevents solder from spreading and adhering thereto. The material is, for example, carbon or a metal material having an oxide film formed on its surface. The positioning jig 30 includes a front surface 30a having an approximately rectangular shape in plan view, and includes a long side surface 30a1, a short side surface 30a2, a long side surface 30a3, and a short side surface 30a4 sequentially enclosing the front surface 30a in four directions. In addition, positioning areas 32a, 32b, 32c, and 32d defined by a horizontal frame 31a and a vertical frame 31b are formed in the front surface 30a. Each of the positioning areas 32a, 32b, 32c, and 32d is sufficiently large such that a corresponding one of the insulated circuit boards 11 is stored, and may be larger than a corresponding one of the placement areas 3c1, 3c2, 3c3, and 3c4 of the heat dissipation base 3. The front surface 30a of the positioning jig 30 may have the same shape as the front surface 3a of the heat dissipation base 3. The front surface 30a of the positioning jig 30 may have any size as long as the positioning areas 32a, 32b, 32c, and 32d are formed. After the positioning jig 30 is set on the front surface 3a of the heat dissipation base 3, the outer resist portion 4b of the resist 4 may be located under edge portions of the positioning areas 32a, 32b, 32c, and 32d of the positioning jig 30. Alternatively, the outer resist portion 4b of the resist 4 may be formed such that part of the outer resist portion 4b is seen on the inner side of the edge portions of the positioning areas 32a, 32b, 32c, and 32d of the positioning jig 30, the edge portions being parallel to the long side surface 30a1, the short side surface 30a2, the long side surface 30a3, and the short side surface 30a4 in plan view.

In addition, the width (the length in the width direction) of the horizontal frame 31a and the vertical frame 31b may be less than the distance W between any two of the placement areas 3c1, 3c2, 3c3, and 3c4. If the distance W is 2 mm, the width of the horizontal frame 31a and the vertical frame 31b may be, for example, 1.75 mm. Thus, in plan view, the inner resist portion 4a formed on the heat dissipation base 3 is viewed from both sides of the horizontal frame 31a and from both sides of the vertical frame 31b, the inner resist portion 4a extending in a longitudinal direction perpendicular to the width direction.

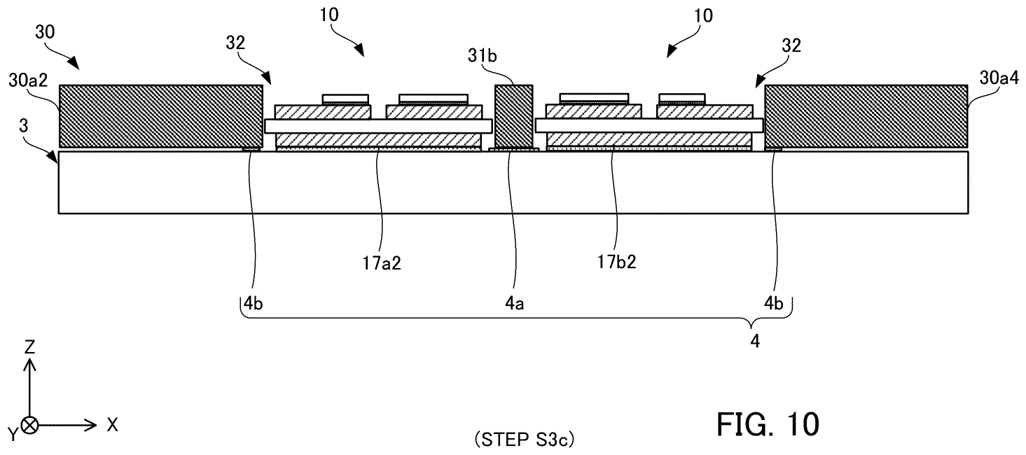

Next, solder plates are set on the front surface 3a of the heat dissipation base 3 (step S3b in FIG. 4). Specifically, solder plates are set on the placement areas 3c1, 3c2, 3c3, and 3c4 of the heat dissipation base 3 (see FIG. 10, which will be described below and which illustrates solder plates 17a2 and 17b2) through the positioning areas 32a, 32b, 32c, and 32d of the positioning jig 30 set on the heat dissipation base 3.

Next, the semiconductor units 10 are set on the front surface 3a of the heat dissipation base 3 (step S3c in FIG. 4). This process will be described with reference to FIG. 10. FIG. 10 is a sectional view illustrating the semiconductor unit bonding process (setting of the semiconductor units) included in the semiconductor device manufacturing method according to the first embodiment. FIG. 10 is a sectional view corresponding to FIG. 9.

The semiconductor units 10 are set on the placement areas 3c1, 3c2, 3c3, and 3c4 of the heat dissipation base 3 via solder plates through the positioning areas 32a, 32b, 32c, and 32d of the positioning jig 30 set on the heat dissipation base 3, as illustrated in FIG. 10. FIG. 10 illustrates the solder plates 17a2 and 17b2.

Next, the heat dissipation base 3, the solder plates, and the semiconductor units 10 are heated (step S3d in FIG. 4). This heating melts the solder plates, and the resultant molten solder spreads on the front surface 3a of the heat dissipation base 3. In this step, the spreading of the molten solder is prevented by the resist 4.

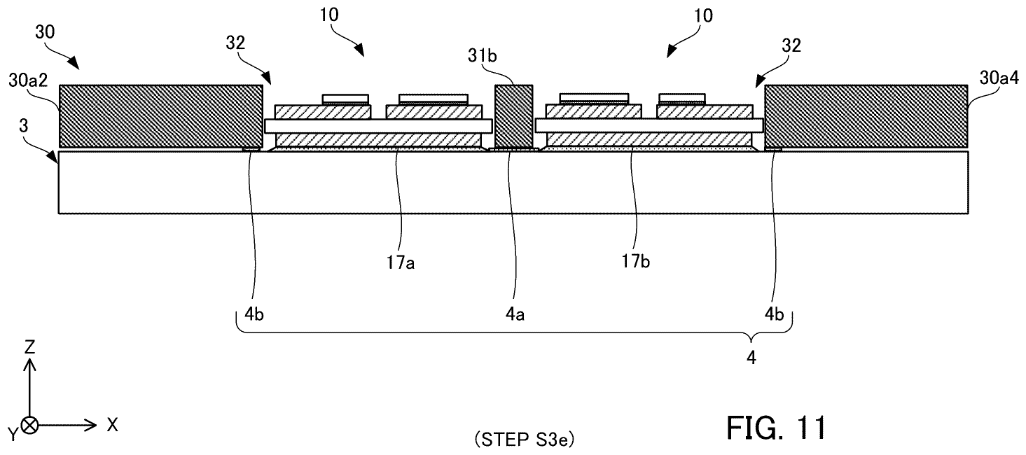

Next, the heat dissipation base 3, the solder, and the semiconductor units 10 are cooled (step S3e in FIG. 4). This step will be described with reference to FIG. 11. FIG. 11 is a sectional view illustrating the semiconductor unit bonding process (cooling) included in the semiconductor according to the first device manufacturing method embodiment. FIG. 11 is a sectional view corresponding to FIG. 10.

By this cooling, the molten solder is cured, and as illustrated in FIG. 11, the insulated circuit boards 11 of the semiconductor units 10 are bonded to the front surface 3a of the heat dissipation base 3 via the solder layers (the solder layers 17a and 17b in FIG. 11). In this step, the semiconductor units 10 are located on their respective placement areas 3cl, 3c2, 3c3, and 3c4 of the heat dissipation base 3.

Next, the positioning jig 30 is removed (step S3f in FIG. 4). From the state illustrated in FIG. 11, the positioning jig 30 is removed. In this way, the individual semiconductor units 10 are bonded to the front surface 3a of the heat dissipation base 3 via the solder layers.

Next, a case attachment process for attaching the case 2 to the heat dissipation base 3 is performed (step S4 in FIG. 5). The case 2 is attached to the heat dissipation base 3 via adhesive. In this step, the semiconductor units 10 are stored in the storage area 22 of the case 2. In addition, the inner end portions of the external connection terminals 23 are disposed to face the insulated circuit boards 11 of the semiconductor units 10.

Next, a wiring process for wiring the semiconductor units 10 is performed (step S5 in FIG. 5). The inner end portions of the external connection terminals 23 of the case 2 are bonded to their respective conductive plates 13b of the insulated circuit boards 11. This bonding is, for example, ultrasonic bonding. As needed, the semiconductor units 10 may be wired with wires.

Next, a sealing process for sealing the storage area 22 of the case 2 with sealing material is performed (step S6 in FIG. 5). Specifically, sealing material is injected into the storage area 22 of the case 2, so as to seal the semiconductor units 10, the wires, etc., stored in the storage area 22. As a result, the semiconductor device 1 illustrated in FIGS. 1 and 2 is obtained.

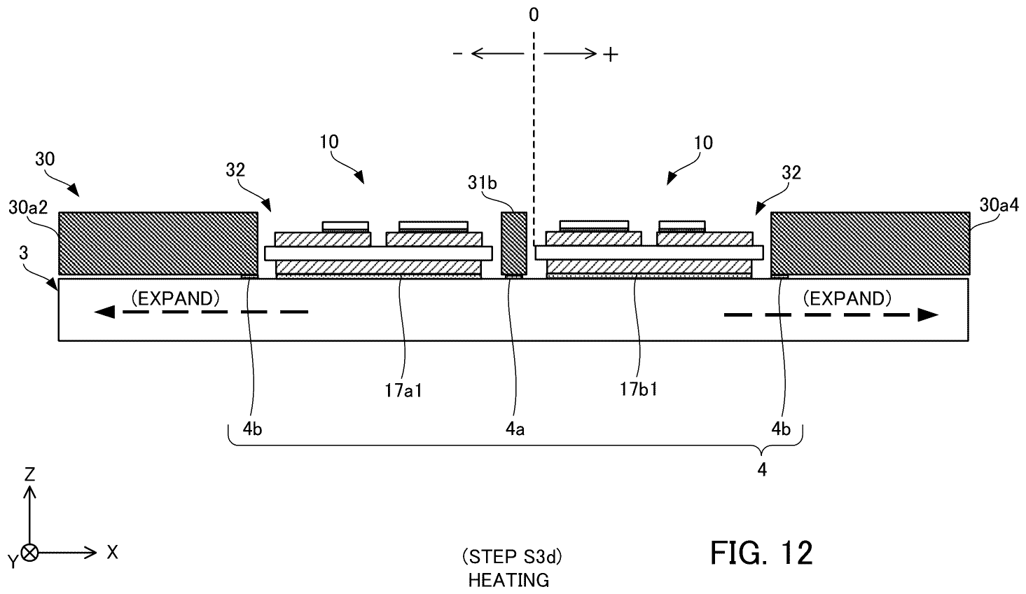

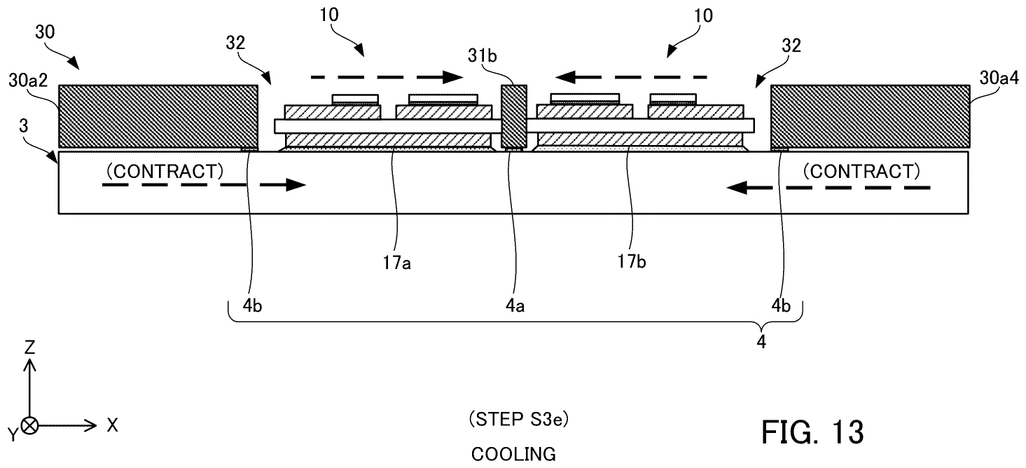

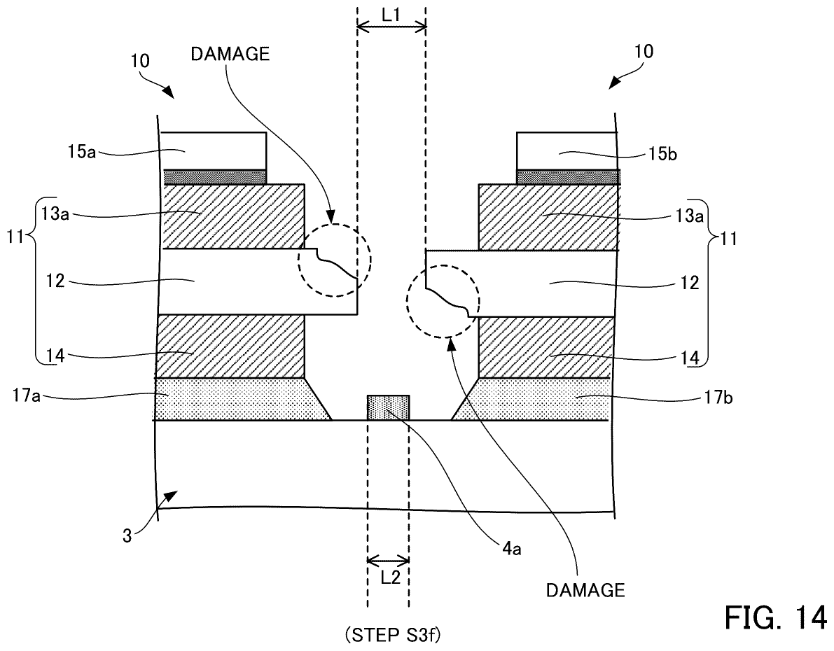

Next, a semiconductor device according to a reference example will be described. The semiconductor device according to the reference example has same construction as that of the semiconductor device 1, except that the inner resist portion 4a of the resist 4 of the semiconductor device according to the reference example does not come in contact with the edge portion 17a1 of the solder layer 17a, the edge portion 17a1 facing the solder layer 17b and does not come in contact with the edge portion 17b1 of the solder layer 17b, the edge portion 17b1 facing the solder layer 17a. For example, the inner resist portion 4a is formed in the middle of the space between the solder layers 17a and 17b. A method for manufacturing the semiconductor device including this inner resist portion 4a will be described with reference to FIGS. 4, 5, and 12 to 14. FIG. 12 is a sectional view illustrating a semiconductor unit bonding process (heating) included in a semiconductor device manufacturing method according to the reference example. FIG. 13 is a sectional view illustrating the semiconductor unit bonding process (cooling) included in the semiconductor device manufacturing method according to the reference example. FIG. 14 is a sectional view of a main part, illustrating the semiconductor unit bonding process (removal of a positioning jig) included in the semiconductor device manufacturing method according to the reference example. FIGS. 12 and 13 are each a sectional view corresponding to FIG. 10. FIG. 14 is an enlarged view of the space between semiconductor units 10 after removal of the positioning jig 30. A case in which the semiconductor device is seen in the +Y direction will hereinafter be described. The same description will also be applied to a case in which the semiconductor device is seen in the +X direction.

The semiconductor device according to the reference example is also manufactured in accordance with the flowchart in FIGS. 4 and 5. The following description of the manufacturing method in accordance with the flowchart in FIGS. 4 and 5 will be simplified or omitted, as needed.

First, as in the first embodiment, the preparation process (step S1 in FIG. 4) is performed. In this step, the heat dissipation base 3 is also prepared (step S1a in FIG. 4), and the resist 4 is formed on the front surface 3a of the heat dissipation base 3 (step S1b in FIG. 4). The inner resist portion 4a of the resist 4 is formed in the middle of the space between two of the placement areas 3c1, 3c2, 3c3, and 3c4 on the front surface 3a of the heat dissipation base 3, without being in contact with the adjacent solder layers. In addition, the width L2 of the inner resist portion 4a is, for example, less than the distance L1 between semiconductor units 10 (insulated circuit boards 11), as illustrated in FIG. 14.

Next, as in the first embodiment, the unit assembly process (step S2 in FIG. 4) and the semiconductor unit bonding process (step S3 in FIG. 4) are performed sequentially. In the semiconductor unit bonding process, the positioning jig 30 is set on the front surface 3a of the heat dissipation base 3 (step S3a in FIG. 4). The solder plates 17a2 and 17b2 are set on the placement areas 3cl, 3c2, 3c3, and 3c4 of the front surface 3a of the heat dissipation base 3 through the positioning areas 32a, 32b, 32c, and 32d of the positioning jig 30 (step S3b in FIG. 4), and the semiconductor units 10 are set on the solder plates 17a2 and 17b2 (step S3c in FIG. 4).

Next, the heat dissipation base 3, the solder plates 17a2 and 17b2, and the semiconductor units 10 are heated (step S3d in FIG. 4). Because of this heating, the solder melted from the solder plates 17a2 and 17b2 spreads on the front surface 3a of the heat dissipation base 3. In addition, in this step, as the heat dissipation base 3 is heated, the heat dissipation base 3 expands mainly to the outer side. For example, when seen in the +Y direction, the heat dissipation base 3 expands in the +X directions as illustrated in FIG. 12.

Next, the heat dissipation base 3, the molten solder, and the semiconductor units 10 are cooled (step S3e in FIG. 4). As the molten solder is cooled and cured, the molten solder begins to bond the semiconductor units 10 to the heat dissipation base 3. In addition, as the heat dissipation base 3 is cooled, the heat dissipation base 3 contracts in the ±X directions as illustrated in FIG. 13. Since the semiconductor units 10 are bonded to the heat dissipation base 3, as the heat dissipation base 3 contracts, the semiconductor units 10 are displaced toward the center in the ±X directions.

Recent years, the space between each pair of semiconductor units 10 disposed on the front surface 3a of the heat dissipation base 3 has been reduced in order to dispose many semiconductor units 10 on the heat dissipation base 3. In addition, in order to reduce the size of a semiconductor device, the space between each pair of semiconductor units 10 needs to be reduced. If the space between each pair of semiconductor units 10 is reduced in order to densely mount the semiconductor units 10 (the insulated circuit boards 11) on the heat dissipation base 3, when the heat dissipation base 3 contracts due to the cooling, the semiconductor units 10 bonded to the heat dissipation base 3 are displaced toward the center of the heat dissipation base 3 in plan view. For example, as illustrated in FIG. 13, neighboring semiconductor units 10 that are displaced toward the center in the ±X directions hold the vertical frame 31b of the positioning jig 30. Although not illustrated, when seen in the +X direction, the horizontal frame 31a of the positioning jig 30 is also held by neighboring semiconductor units 10.

If the positioning jig 30 is held by neighboring semiconductor units 10, the positioning jig 30 is not easily removed in step S3f in FIG. 4. In some cases, the positioning jig 30 may be firmly held by neighboring semiconductor units 10 and may fail to be removed.

In addition, when neighboring semiconductor units 10 hold the vertical frame 31b of the positioning jig 30, the neighboring semiconductor units 10 are damaged. As a result, for example, as illustrated in FIG. 14, end portions of the insulating plates 12 of the insulated circuit boards 11 included in the semiconductor units 10 are damaged and broken.

As described above, when the semiconductor units 10 (semiconductor chips 15a and 15b) are densely mounted, assembly malfunctions easily occur, and the manufacturing cost is increased. In addition, the insulated circuit boards 11 are broken, and the quality of the semiconductor device is deteriorated.

In contrast, the semiconductor device 1 according to the first embodiment, the width L2 of the inner resist portion 4a is greater than the distance L1 between each pair of semiconductor units 10 (insulated circuit boards 11). In addition, the inner resist portion 4a is in contact with edge portions of its neighboring solder layers, the edge portions facing each other.

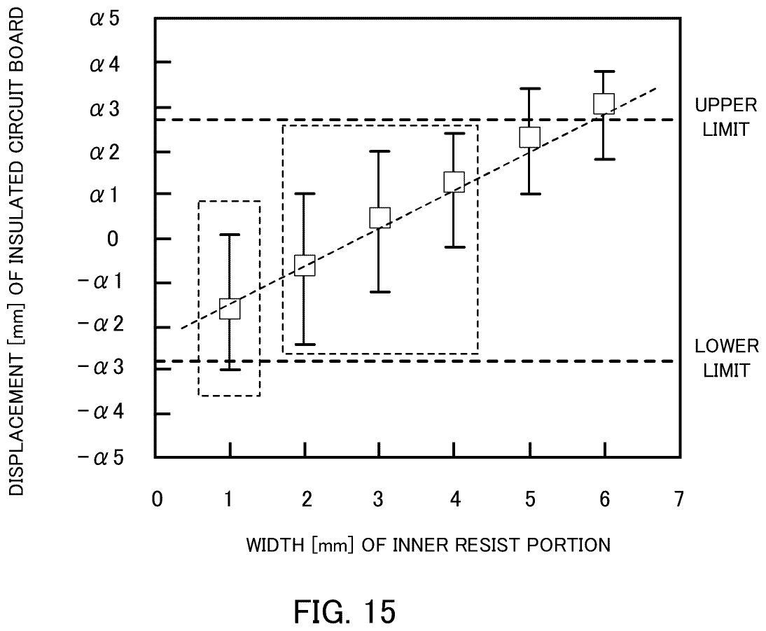

Each insulated circuit board 11 bonded to the front surface 3a of the heat dissipation base 3 is displaced as the heat dissipation base 3 expands and contracts in steps S3s and S3e in FIG. 4. Hereinafter, this displacement with respect to the width of the inner resist portion 4a will be described with reference to FIG. 15. FIG. 15 is a graph illustrating the displacement of an insulated circuit board with respect to the width of the resist.

For example, in FIG. 12, first, an insulated circuit board 11 was disposed on the front surface 3a of the heat dissipation base 3 via a solder plate 17b1 and was bonded to the front surface 3a by heating and cooling. Next, the displacement of the insulated circuit board 11 was measured with respect to the width L2 of the inner resist portion 4a. The measurement was conducted a plurality of times with different widths L2.

The horizontal axis in FIG. 15 represents the width L2 (mm) of the inner resist portion 4a of the resist. The vertical axis in FIG. 15 represents the displacement (mm) of the insulated circuit board 11 with respect to the width L2 of the inner resist portion 4a.

The displacement is represented by the distance that the insulated circuit board 11 has moved from a present reference location. On the vertical axis in FIG. 15, 0 represents the reference location, and α1, α2, α3, α4, and α5 represent numerical values. These numerical values have a relationship of α1<α2<α3<α4<α5. For example, the location of an end portion of the insulated circuit board 11 in FIG. 12 is the reference location. That is, this location is represented by 0. How much the insulated circuit board 11 has moved from this reference location toward (in the −X direction) the vertical frame 31b of the positioning jig 30 is the displacement (in the negative direction). How much the insulated circuit board 11 has moved from this reference location in the direction opposite to the vertical frame 31b of the positioning jig 30 (in the +X direction) is the displacement (in the positive direction).

In addition, the lower limit of the displacement in FIG. 15 is the displacement that causes the insulated circuit board 11 to be displaced in the negative direction and to come in contact with the positioning jig 30. The upper limit of the displacement in FIG. 15 is the displacement that causes the insulated circuit board 11 to move in the positive direction and to move over the space in which placement of the insulated circuit board 11 is allowed. That is, if the displacement in FIG. 15 exceeds the upper limit, the insulated circuit boards 11 are not densely mounted.

FIG. 15 illustrates a plurality of measurement results of the displacement of the insulated circuit board 11 for each width L2 of the inner resist portion 4a. Thus, as illustrated in FIG. 15, for each width L2 of the inner resist portion 4a, different displacements of the insulated circuit board 11 were obtained. For each width L2 of the inner resist portion 4a, a square represents an average of the plurality of measurement results of the displacement of the insulated circuit board 11.

As illustrated in FIG. 15, the above-described measurement indicates that the displacement of the insulated circuit board 11 generally shifts in the positive direction as the width L2 of the inner resist portion 4a increases. This may be because of the following reason. First, because the inner resist portion 4a has water repellency against the molten solder, the inner resist portion 4a prevents the molten solder from spreading. Second, it is also conceivable that the inner resist portion 4a prevents the insulated circuit board 11 on the solder from being displaced with the contraction of the heat dissipation base 3.

Although the displacement of the insulated circuit board 11 shifts in the positive direction as the width L2 of the inner resist portion 4a increases, when the width L2 of the inner resist portion 4a is 1 mm or less, the displacement of the insulated circuit board 11 could exceed the lower limit. When the width L2 of the inner resist portion 4a is 2 mm or greater, the displacement of the insulated circuit board 11 does not exceed the lower limit. Thus, when the width L2 of the inner resist portion 4a is 2 mm or more, the insulated circuit board 11 does not come in contact with the vertical frame 31b of the positioning jig 30. However, when the width L2 of the inner resist portion 4a is 5 mm or greater, the displacement of the insulated circuit board 11 exceeds the upper limit. Thus, it is not suitable to set the width L2 of the inner resist portion 4a to 5 mm or greater when the insulated circuit board 11 needs to be densely mounted on the heat dissipation base 3.

Therefore, when the width L2 of the inner resist portion 4a is 1 mm or greater and 5 mm or less, preferably, between 2 mm and 4 mm, inclusive, it is possible to densely mount the insulated circuit boards 11, which are displaced with the expansion and contraction of the heat dissipation base 3, on the heat dissipation base 3, without having the insulated circuit boards 11 come in contact with the vertical frame 31b of the positioning jig 30.

In FIG. 12, as described above, the distance W of the space between neighboring insulated circuit boards 11 is between 1.8 mm and 2.2 mm, inclusive. Thus, since the width L2 of the inner resist portion 4a formed in the space between the neighboring insulated circuit boards 11 is preferably between 2 mm and 4 mm, inclusive, the inner resist portion 4a is in contact with the edge portion 17a1 of the solder layer 17a, the edge portion 17a1 facing the solder layer 17b, and is in contact with the edge portion 17b1 of the solder layer 17b, the edge portion 17b1 facing the solder layer 17a.

The above-described semiconductor device 1 includes neighboring insulated circuit boards 11 and a heat dissipation base 3. The heat dissipation base 3 has a front surface 3a on which one of the insulated circuit boards 11 is bonded via a solder layer 17a and on which another insulated circuit board 11 is bonded via a solder layer 17b. In addition, the neighboring insulated circuit boards 11 face each other with a space therebetween, and an inner resist portion 4a is formed in the space on the front surface 3a along the solder layers 17a and 17b. The inner resist portion 4a is in contact with an edge portion 17a1 of the solder layer 17a, the edge portion 17a1 facing the solder layer 17b, and is in contact with an edge portion 17b1 of the solder layer 17b, the edge portion 17b1 facing the solder layer 17a. Since the inner resist portion 4a is formed on the heat dissipation base 3, even when the heat dissipation base 3 expands or contracts due to the heating and cooling in the process of manufacturing the semiconductor device 1, the bonding location of each insulated circuit board 11 is controlled. Thus, even when the insulated circuit boards 11 are densely mounted on the heat dissipation base 3, occurrence of assembly malfunctions in the process of manufacturing the semiconductor device 1 is prevented. Therefore, in the semiconductor device 1, the insulated circuit boards 11 are densely mounted.

### Second Embodiment

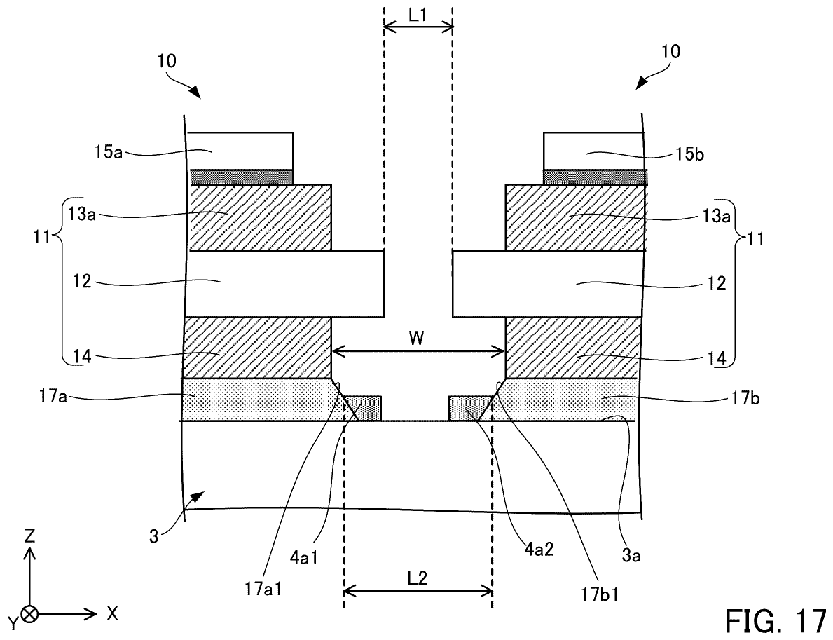

A semiconductor device according to a second embodiment includes an inner resist portion 4a, which is different from the inner resist portion 4a of the semiconductor device 1 according to the first embodiment. The inner resist portion 4a according to the second embodiment includes a first resist portion, which is in contact with the edge portion 17a1 of the solder layer 17a, and includes a second resist portion, which is in contact with the edge portion 17b1 of the solder layer 17b and is away from the first resist portion. The semiconductor device according to the second embodiment will be described with reference to FIGS. 16 and 17.

FIG. 16 is a plan view of the semiconductor device according to the second embodiment. FIG. 17 is a sectional view of a main part of the semiconductor device according to the second embodiment. FIG. 16 is a plan view corresponding to FIG. 1 according to the first embodiment. FIG. 17 corresponds to FIG. 3 according to the first embodiment, and is a sectional view taken along a dash-dotted line Y-Y in FIG. 16.

This semiconductor device 1a according to the second embodiment has the same construction as that of the semiconductor device 1 according to the first embodiment, except the resist 4. The resist 4 of the semiconductor device 1a includes a first resist portion 4a1 and a second resist portion 4a2, in addition to the outer resist portion 4b.

As illustrated in FIGS. 16 and 17, the first resist portion 4a1 is formed to come in contact with the edge portion 17a1 of the solder layer 17a along the edge portion 17a1. The second resist portion 4a2 is formed to come in contact with the edge portion 17b1 of the solder layer 17b along the edge portion 17b1. In addition, the second resist portion 4a2 is formed to be in parallel with and away from the first resist portion 4a1. FIGS. 16 and 17 illustrate the space between neighboring insulated circuit boards 11 seen in the +Y direction. When seen in the +X direction, the first resist portion 4a1 and the second resist portion 4a2 are also formed in the same way as illustrated in FIGS. 16 and 17 in the space between neighboring insulated circuit boards 11.

The width L2 between a side portion of the first resist portion 4a1 and a side portion of the second resist portion 4a2, the former side portion being in contact with the edge portion 17a1 of the solder layer 17a and the latter side portion being in contact with the edge portion 17b1 of the solder layer 17b, is the same as the width L2 of the inner resist portion 4a according to the first embodiment. As is the case with the above-described inner resist portion 4a, the first resist portion 4a1 and the second resist portion 4a2 also control the bonding location of each insulated circuit board 11, even when the heat dissipation base 3 expands and contracts due to the heating and cooling in the process of manufacturing the semiconductor device 1a.

Thus, even when the insulated circuit boards 11 are densely mounted on the heat dissipation base 3, occurrence of assembly malfunctions in the process of manufacturing the semiconductor device 1a is prevented. Therefore, in the semiconductor device 1a, the insulated circuit boards 11 are densely mounted.

According to the disclosed technique, it is possible to densely mount boards while controlling the bonding location of each board.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a first board and a second board facing each other with a space therebetween;
a heat dissipation base having a front surface, on which the first board is bonded via a first solder layer and the second board is bonded via a second solder layer; and
a resist formed along the first solder layer and the second solder layer, wherein
the first solder layer has an edge portion thereof facing the second solder layer, said edge portion being a first edge portion,
the second solder layer has an edge portion thereof facing the first solder layer, said edge portion being a second edge portion, and
the resist is in contact with the first edge portion and the second edge portion.

2. The semiconductor device according to claim 1,
wherein the first board includes:
a first insulating plate,
a first conductive plate formed on a front surface of the first insulating plate, and
a first metal plate formed on a rear surface of the first insulating plate and bonded to the front surface of the heat dissipation base via the first solder layer; and
wherein the second board includes:
a second insulating plate,
a second conductive plate formed on a front surface of the second insulating plate, and
a second metal plate formed on a rear surface of the second insulating plate and bonded to the front surface of the heat dissipation base via the second solder layer.

3. The semiconductor device according to claim 2, wherein in a first direction parallel to the front surface of the heat dissipation base, a distance between the first solder layer and the second solder layer is greater than a distance between the first insulating plate of the first board and the second insulating plate of the second board.

4. The semiconductor device according to claim 1, wherein the resist contains carbon or a nickel oxide film as a main component thereof.

5. The semiconductor device according to claim 1, wherein in a first direction parallel to the front surface of the heat dissipation base, a width of the resist is greater than 1 mm and less than 5 mm.

6. The semiconductor device according to claim 5, wherein in the first direction, the width of the resist is between 2 mm and 4 mm, inclusive.

7. The semiconductor device according to claim 1, wherein in a first direction parallel to the front surface of the heat dissipation base, a distance between the first edge portion of the first solder layer and the second edge portion of the second solder layer is between 1.5 mm and 2.5 mm, inclusive.

8. The semiconductor device according to claim 1, wherein the resist includes
a first resist portion that is in contact with the first edge portion, and
a second resist portion that is in contact with the second edge portion and that is away from the first resist portion.

9. The semiconductor device according to claim 1, wherein a thickness of the resist is less than a thickness of each of the first solder layer and the second solder layer.
